(19) United States
(12) Patent Application Publication
(10) Pub. No.: US 2021/0408187 A1
(43) Pub. Date: Dec. 30, 2021

(54) ORGANIC LIGHT-EMITTING DIODE SUBSTRATE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Qi OUYANG, Wuhan, Hubei (CN); Min ZHENG, Wuhan, Hubei (CN); Yang ZHOU, Wuhan, Hubei (CN)

(21) Appl. No.: 16/771,227

(22) PCT Filed: Jun. 18, 2019
(86) PCT No.: PCT/CN2019/091751

§ 371 Date: Jun. 10, 2020

(30) Foreign Application Priority Data
May 27, 2019 (CN) 201910448182.1

(51) Int. Cl. H01L 27/32

(52) U.S. Cl. CPC H01L 27/3248; H01L 51/0097; H01L 27/326

(57) ABSTRACT

An organic light-emitting diode (OLED) display panel is provided and includes a plurality of pixel regions spaced apart from each other. Each of the pixel regions includes an active region and a non-active region surrounding the active region. The active region includes a base substrate, a thin-film transistor (TFT) layer disposed on the base substrate, a planarization layer disposed on the TFT layer, and an anode disposed on the planarization layer. The anode is in contact with the TFT layer via an anode connection hole that passes through the planarization layer. The non-active area is provided with a photosensor placement region on the non-active area and the photosensor placement region is spaced apart from the anode connection hole.

### FIELD OF INVENTION

The present disclosure relates to a field of display technologies, and more particularly to an organic light-emitting diode (OLED) substrate.

### BACKGROUND OF INVENTION

Organic light-emitting display devices possess many outstanding properties, such as self-luminousity, low driving voltage, high electroluminescent efficiency, short response times, high resolution and contrast, near 180 degree viewing angles, wide range of working temperatures, amenability to flexible displays, large scale full-color display, etc. The organic light-emitting display devices are considered to be display panels having greatest potential for development.

According to driving methods, organic light-emitting diodes (OLEDs) can be divided into two types: passive matrix organic light-emitting diodes (PMOLEDs) and active matrix organic light-emitting diodes (AMOLEDs), namely direct addressing and thin film transistor matrix addressing. Among them, AMOLEDs have pixels arranged in an array and belong to active-display type. AMOLEDs have a high luminous efficiency and are generally used as large-sized and high-definition display devices.

OLED devices generally include a substrate, an anode disposed on the substrate, a hole injection layer disposed on the anode, a hole transport layer disposed on the hole injection layer, a light-emitting layer disposed on the hole transport layer, an electron transport layer disposed on the light-emitting layer, an electron injection layer disposed on the electron transport layer, and a cathode disposed on the electron injection layer. Illumination principle of OLED devices is that semiconductor materials and organic luminescent materials are driven by electric fields and result in luminescence due to carrier injection and recombination. Specifically, OLED devices generally employ indium tin oxide (ITO) electrodes and metal electrodes as anodes and cathodes of the devices, respectively. Electrons and holes are driven by a certain voltage and are injected from the cathodes and the anodes to the electron transport layer and the hole transport layer, respectively. The electrons and the holes respectively migrate through the electron transport layer and the hole transport layer to the light-emitting layers. The electrons meet the holes in the light-emitting layer to form excitons and excite light-emitting molecules. The light-emitting molecules emit visible light through radiation relaxation.

Please refer to FIG. 1 and FIG. 2, when an OLED device is applied to an electronic device having a camera module, a distance between an anode connection hole 41′ and a photosensor placement region 1021′ of the OLED substrate of the prior art is close to each other. An area of the photosensor placement region 1021′ is thus small. Therefore, a shape of the photo sensor placement region 1021′ can only be an irregular shape which is similar to a triangle. When a photo sensor of the camera module is subsequently placed within the photosensor placement region 1021′, an amount of light received by the camera module are reduced due to an insufficient amount of light throughput. Photographic quality of the electronic devices is directly affected. Therefore, it is necessary to improve the OLED devices to enhance shooting quality of the camera module.

### SUMMARY OF INVENTION

An object of the present disclosure to provide an organic light-emitting diode (OLED) substrate that can increase an area of the photosensor placement region, thereby enhancing a photographing quality of the camera module.

To achieve the above object, the present disclosure provides an organic light-emitting diode (OLED) substrate for an electronic device having a camera module, comprising: a plurality of pixel regions spaced apart from each other; wherein each of the pixel regions comprises an active region and a non-active region surrounding the active region;

wherein the active region comprises: a base substrate, a thin-film transistor (TFT) layer disposed on the base substrate, a planarization layer disposed on the TFT layer, and an anode disposed on the planarization layer; and wherein the anode is in contact with the TFT layer via an anode connection hole that passes through the planarization layer; and

wherein the non-active area comprises a photosensor placement region on the non-active area, the photosensor placement region is spaced apart from the anode connection hole; and wherein the photo sensor placement region is configured to dispose a photosensor of the camera module.

A distance between the photosensor placement region and the anode connection hole is more than 2 microns.

A shape of the photosensor placement region is a regular shape.

The TFT layer comprises: an active layer disposed on the base substrate; a first gate insulating layer covering the base substrate and the active layer; a first gate disposed on the first gate insulating layer; a second gate insulating layer covering the first gate insulating layer and the first gate; a second gate disposed on the second gate insulating layer; an interlayer insulating layer covering the second gate insulating layer and the second gate; and a source and a drain disposed on the interlayer insulating layer.

The source is in contact with the active layer via a source connection hole that passes through the interlayer insulating layer, the second gate insulating layer, and the first gate insulating layer.

The drain is in contact with the active layer via a drain connection hole that passes through the interlayer insulating layer, the second gate insulating layer, and the first gate insulating layer.

The anode is in contact with the drain via an anode connection hole that passes through the planarization layer.

The OLED substrate further comprises a buffer layer disposed between the base substrate and the TFT layer.

The OLED substrate further comprises a pixel defining layer disposed on the planarization layer and the anode, the pixel defining layer defines a through hole in the pixel defining layer, and the through hole exposes the anode.

A material of the base substrate is polyimide.

Beneficial effects of the present disclosure: an OLED substrate of the present disclosure includes a plurality of pixel regions spaced apart from each other. Each of the pixel regions includes an active region and a non-active region surrounding the active region. The active region includes a base substrate, a thin-film transistor (TFT) layer disposed on the base substrate, a planarization layer disposed on the TFT layer, and an anode disposed on the planarization layer. The anode is in contact with the TFT layer via an anode connection hole that passes through the planarization layer. The non-active area is provided with a photosensor placement region on the non-active area and the photosensor placement region is spaced apart from the anode connection hole, so that area of the photosensor placement area can be increased. When the OLED substrate is applied to an electronic device having a camera module, a photosensor of the camera module is placed within the photosensor placement region so that a light receiving area of the photosensor can be increased, thereby enhancing a shooting quality of the camera module.

### DESCRIPTION OF DRAWINGS

In order to further understand features and technical schemes of the present disclosure, please refer to the detailed description of the present disclosure and the accompanying drawings. However, the accompanying drawings provided herein are only used as reference and description. The accompanying drawings should not be construed as a limitation on the scope of the present disclosure.

In the drawings,

FIG. 1 is a schematic view of a conventional OLED substrate;

FIG. 2 is a top view of the conventional OLED substrate;

FIG. 3 is a schematic view of an OLED substrate of the present disclosure; and

FIG. 4 is a top view of the OLED substrate of the present disclosure.

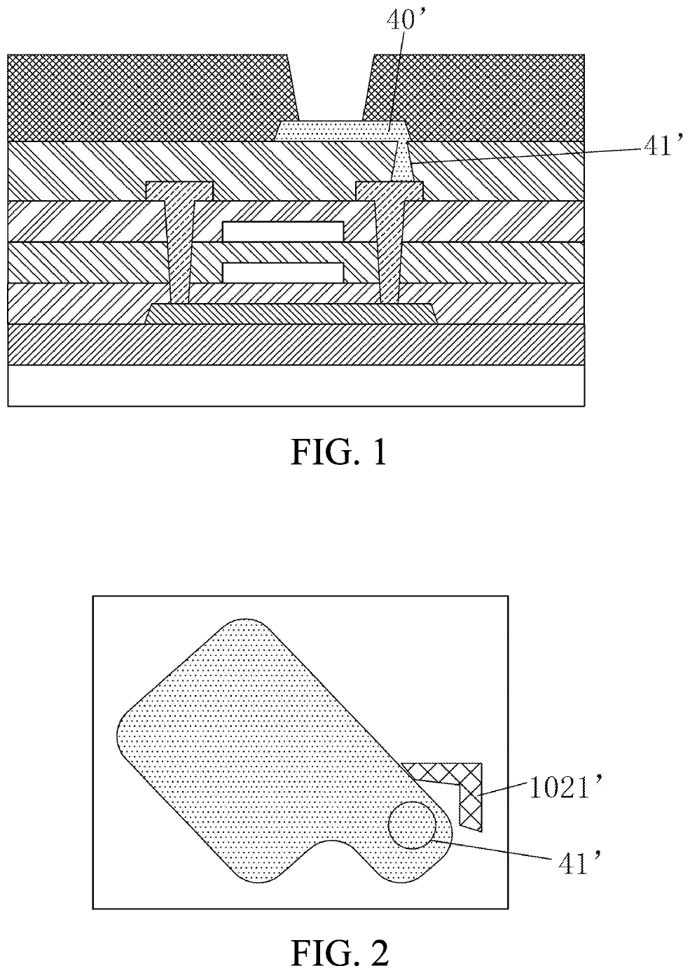

### DETAILED DESCRIPTION OF PREFERRED EMBODIMENTS

For further explaining the technical solutions and the effects of the present invention, the embodiments of the present invention will be further described in combination with the accompanying drawings of the present invention in follows.

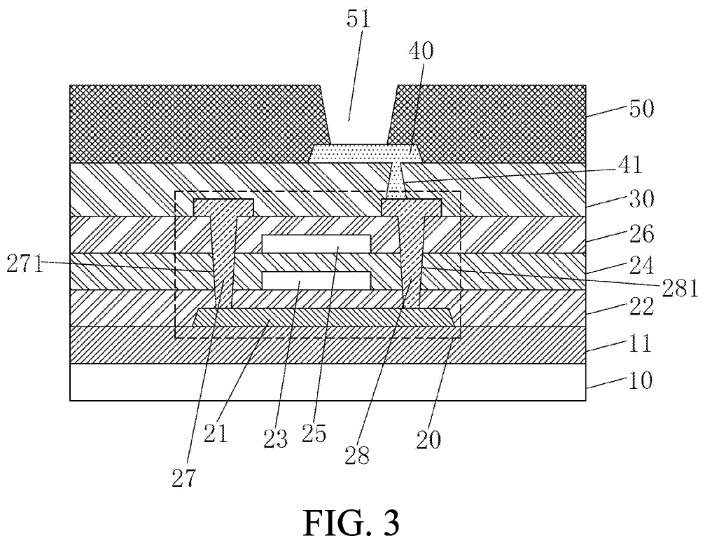

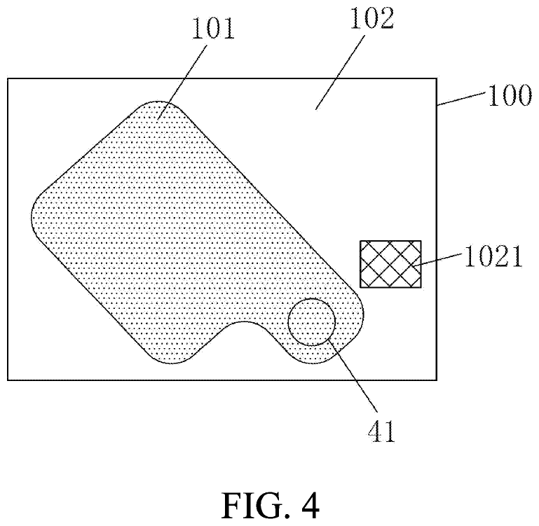

Please refer to FIG. 3 and FIG. 4, the present disclosure provides an organic light-emitting diode (OLED) substrate for an electronic device having a camera module 100, including a plurality of pixel regions 100 spaced apart from each other; wherein each of the pixel regions 100 comprises an active region 101 and a non-active region 102 surrounding the active region;

wherein the active region 101 comprises: a base substrate 10, a thin-film transistor (TFT) layer 20 disposed on the base substrate 10, a planarization layer 30 disposed on the TFT layer 20, and an anode 40 disposed on the planarization layer 30; and wherein the anode 40 is in contact with the TFT layer 20 via an anode connection hole 41 that passes through the planarization layer 30; and

wherein the non-active area 102 comprises a photosensor placement region 1021 on the non-active area 102, the photosensor placement region 1021 is spaced apart from the anode connection hole 41; and wherein the photo sensor placement region is configured to dispose a photosensor of the camera module.

Specifically, a distance between the photosensor placement region 1021 and the anode connection hole 41 is more than 2 microns.

Specifically, a shape of the photosensor placement region 1021 is a regular shape, for example, the regular shape is a circle, a rectangle, a regular pentagon, or a regular hexagon. When the OLED substrate is applied to an electronic device having a camera module, the photosensor of the camera module is placed within the photosensor placement region 1021 so that a light receiving area of the photosensor can be increased, thereby enhancing shooting quality of the camera module.

It should be noted that the present disclosure is by disposing the photosensor placement region to be spaced apart from the anode connection hole, i.e., a position of the anode connection hole 41 is moved by a certain distance (for example, 2-3 microns) with respect to a position of the anode connection hole 41′ of the prior art in a direction which is away from the photosensor placement region 1021, thereby increasing the area of the photosensor placement region 1021. The shape of the photosensor placement region 1021 can be a regular shape. When the OLED substrate is further applied to an electronic device having a camera module, the photosensor of the camera module is placed within the photosensor placement region 1021 so that a light receiving area of the photosensor can be increased, thereby enhancing shooting quality of the camera module.

Specifically, the TFT layer 20 includes an active layer 21 disposed on the base substrate 10; a first gate insulating layer 22 covering the base substrate 10 and the active layer 21; a first gate 23 disposed on the first gate insulating layer 22; a second gate insulating layer 24 covering the first gate insulating layer 22 and the first gate 23; a second gate 25 disposed on the second gate insulating layer 24; an interlayer insulating layer 26 covering the second gate insulating layer 24 and the second gate 25; and a source 27 and a drain 28 disposed on the interlayer insulating layer 26.

The source 27 is in contact with the active layer 21 via a source connection hole 271 that passes through the interlayer insulating layer 26, the second gate insulating layer 24, and the first gate insulating layer 22.

The drain 28 is in contact with the active layer 21 via a drain connection hole 281 that passes through the interlayer insulating layer 26, the second gate insulating layer 24, and the first gate insulating layer 22.

Specifically, the anode 40 is in contact with the drain 28 via an anode connection hole 41 that passes through the planarization layer 30.

Specifically, the anode 40 is in contact with the drain electrode 28 through an anode connection hole 41 penetrating the planarization layer 30.

Specifically, the OLED substrate further comprises a buffer layer 11 disposed between the base substrate 10 and the TFT layer 20.

Specifically, the buffer layer 11 is disposed on the base substrate 10 by chemical vapor deposition (CVD).

Specifically, the OLED substrate further comprises a pixel defining layer 50 disposed on the planarization layer 30 and the anode 40; the pixel defining layer 50 defines a through hole 51 in the pixel defining layer 50, and the through hole 51 exposes the anode 40.

Furthermore, the OLED substrate further includes a hole injection layer (not shown) disposed on the anode 40, a hole transport layer (not shown) disposed on the hole injection layer, an light-emitting layer (not shown) disposed on the hole transport layer, an electron transport layer (not shown) disposed on the light-emitting layer, an electron injection layer (not shown) disposed on the electron transport layer, and a cathode disposed on the electron injection layer (not shown), thereby forming a complete OLED device.

Specifically, a material of the base substrate 10 is polyimide (PI) and the OLED substrate is a flexible OLED substrate.

Specifically, a manufacturing process of the OLED substrate is: forming a base substrate 10 by slit coating, forming an active layer 21 on the base substrate 10 by chemical vapor deposition; forming a first gate insulating layer 22 of the base substrate 10 and the active layer 21 by chemical vapor deposition; forming a first gate electrode 23 on the first gate insulating layer 22 by physical vapor deposition (PVD); forming a second gate insulating layer 24 that covers a first gate insulating layer 22 and the first gate 23 by chemical vapor deposition; forming a second gate 25 on the second gate insulating layer 24 by physical vapor deposition; forming a second gate electrode 26 that covers the second gate insulating layer 24 and the second gate 25 by chemical vapor deposition; etching the interlayer insulating layer 26, the second gate insulating layer 24, and the first gate insulating layer 22 by a photolithography process to form a source connection hole 271 and a drain connection hole 281 that pass through the interlayer insulating layer 26, the second gate insulating layer 24, and the first gate insulating layer 22; forming a source 27 and a drain 28 on the interlayer insulating layer 26 by physical vapor deposition, in which the source 27 and the drain 28 are in contact with the active layer 21 via the source connection hole 271 and the drain connection hole 281, respectively; coating a planarization layer 30 that covers the interlayer insulating layer 26, the source 27 and the drain 28; etching the planarization layer 30 by a photolithography process to form an anode connection hole 41 that exposes the drain electrode 28, in which the position of the anode connection hole 41′ of the present disclosure compared with the prior art, during the etching process, is moved by a certain distance (for example, 2-3 microns) in a direction that is away from the photosensor placement region 1021 to perform etching on the planarization layer 30; forming the anode 40 on the planarization layer 30 by physical vapor deposition, in which the anode 40 is in contact with the drain electrode 28 and passes through the anode connection hole 41.

In summary, the OLED substrate of the present disclosure includes a plurality of pixel regions spaced apart from each other. Each of the pixel regions includes an active region and a non-active region surrounding the active region. The active region includes a base substrate, a thin-film transistor (TFT) layer disposed on the base substrate, a planarization layer disposed on the TFT layer, and an anode disposed on the planarization layer. The anode is in contact with the TFT layer via an anode connection hole that passes through the planarization layer. The non-active area is provided with a photosensor placement region on the non-active area and the photosensor placement region is spaced apart from the anode connection hole, so that area of the photosensor placement area can be increased. When the OLED substrate is applied to an electronic device having a camera module, a photosensor of the camera module is placed within the photosensor placement region so that a light receiving area of the photosensor can be increased, thereby enhancing a shooting quality of the camera module.

In summary, one of ordinarily skill in the art can carry out changes and modifications to the described embodiment according to technical solutions and technical concepts of the present disclosure, and all such changes and modifications are considered encompassed in the scope of protection defined by the clams of the present disclosure.

1. An organic light-emitting diode (OLED) substrate for an electronic device having a camera module, comprising: a plurality of pixel regions spaced apart from each other; wherein each of the pixel regions comprises an active region and a non-active region surrounding the active region;
wherein the active region comprises: a base substrate, a thin-film transistor (TFT) layer disposed on the base substrate, a planarization layer disposed on the TFT layer, and an anode disposed on the planarization layer; and wherein the anode is in contact with the TFT layer via an anode connection hole that passes through the planarization layer; and
wherein the non-active area comprises a photosensor placement region on the non-active area, the photosensor placement region is spaced apart from the anode connection hole; and wherein the photo sensor placement region is configured to dispose a photosensor of the camera module.

2. The OLED substrate of claim 1, wherein a distance between the photosensor placement region and the anode connection hole is more than 2 microns.

3. The OLED substrate of claim 1, wherein a shape of the photosensor placement region is a regular shape.

4. The OLED substrate of claim 1, wherein the TFT layer comprises: an active layer disposed on the base substrate; a first gate insulating layer covering the base substrate and the active layer; a first gate disposed on the first gate insulating layer; a second gate insulating layer covering the first gate insulating layer and the first gate; a second gate disposed on the second gate insulating layer; an interlayer insulating layer covering the second gate insulating layer and the second gate; and a source and a drain disposed on the interlayer insulating layer.

5. The OLED substrate of claim 4, wherein the source is in contact with the active layer via a source connection hole that passes through the interlayer insulating layer, the second gate insulating layer, and the first gate insulating layer.

6. The OLED substrate according to claim 4, wherein the drain is in contact with the active layer via a drain connection hole that passes through the interlayer insulating layer, the second gate insulating layer, and the first gate insulating layer.

7. The OLED substrate of claim 4, wherein the anode is in contact with the drain via an anode connection hole that passes through the planarization layer.

8. The OLED substrate of claim 1, wherein the OLED substrate further comprises a buffer layer disposed between the base substrate and the TFT layer.

9. The OLED substrate of claim 1, wherein the OLED substrate further comprises a pixel defining layer disposed on the planarization layer and the anode, the pixel defining layer defines a through hole in the pixel defining layer, and the through hole exposes the anode.

10. The OLED substrate of claim 1, wherein a material of the base substrate is polyimide.
